(19) United States
(12) Patent Application Publication
(10) Pub. No.: US 2021/0359259 A1
(43) Pub. Date: Nov. 18, 2021

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Dong ZHAN, Wuhan (CN)

(21) Appl. No.: 16/488,371

(22) PCT Filed: Apr. 26, 2019
(86) PCT No.: PCT/CN2019/084598

§ 371 Date: Aug. 23, 2019

(30) Foreign Application Priority Data
Jan. 31, 2019 (CN) 201910098523.7

(51) Int. Cl. H01L 51/52

(52) U.S. Cl. CPC H01L 51/5253; H01L 51/5256

(57) ABSTRACT

The present disclosure provides a display panel and a display devise, and the display panel includes a substrate and an encapsulation film. The encapsulation film disposed on the substrate, and the encapsulation film includes laminated a first inorganic layer, a first organic layer, and a second inorganic layer. A plurality of first protrusions are disposed on a surface of the first inorganic layer facing the first organic layer, and the first organic layer is disposed on the plurality of first protrusions and covers the first inorganic layer.

### FIELD OF THE DISCLOSURE

The present disclosure is related to the field of display technology, and specifically to a display panel and a display device.

### BACKGROUND OF THE DISCLOSURE

Organic Light-Emitting Diode (OLED) is an electric current type light-emitting device. It has attracted wide attention due to its self-illumination, rich color, fast response, wide viewing angle, light weight, and flexible display.

However, because the organic materials are particularly sensitive to the external water and oxygen, it needs to encapsulate OLED devices. The present encapsulation technology uses a simple laminated structure. Therefore, encapsulation films peel off happens, decreasing the reliability of the OLED panel encapsulation and reducing the life of OLED devices.

### SUMMARY OF THE DISCLOSURE

The present disclosure mainly improves the reliability of the OLED panel encapsulation and further increases the life of OLED devices.

First, the present disclosure provides a display panel, comprising:

a substrate; and

an encapsulation film, the encapsulation film disposed on the substrate, and the encapsulation film comprising laminated a first inorganic layer, a first organic layer, and a second inorganic layer; wherein a plurality of first protrusions are disposed on a surface of the first inorganic layer facing the first organic layer, and the first organic layer is disposed on the plurality of first protrusions and covers the first inorganic layer.

wherein each of the plurality of first protrusions comprises a first end portion and a second end portion opposite to each other, and a side portion disposed between the first end portion and the second end portion;

wherein the first organic layer is disposed along the first end portion and the side portion, and the second end portion connects the first inorganic layer;

wherein a plurality of second protrusions are disposed on a surface of the first organic layer facing the first inorganic layer; and

wherein the first protrusions are staggered with the second protrusions, and each of all of the second protrusions is disposed between neighboring two of the first protrusions.

In the display panel of the present disclosure, a plurality of third protrusions are disposed on the surface of the first organic layer facing the second inorganic layer, and a plurality of fourth protrusions are disposed on a surface of the second inorganic layer facing the first organic layer; and

wherein the third protrusions are staggered with the fourth protrusions, and each of all of the third protrusions is disposed between neighboring two of the fourth protrusions.

In the display panel of the present disclosure, each of the first protrusions corresponds to each of the fourth protrusions, and each of the second protrusions corresponds to each of the third protrusions.

In the display panel of the present disclosure, an orthographic projection of the first protrusions on the light-emitting substrate coincides with an orthographic projection of the fourth protrusions on the light-emitting substrate; and

wherein an orthographic projection of the second protrusions on the light-emitting substrate coincides with an orthographic projection of the third protrusions on the light-emitting substrate.

In the display panel of the present disclosure, the encapsulation film further comprises a second organic layer and a third inorganic layer; and

wherein a plurality of fifth protrusions are disposed on the surface of the first inorganic layer facing the second organic layer, the second organic layer is disposed on the plurality of fifth protrusions and covers the first inorganic layer, and the third inorganic layer is disposed on the second organic layer.

In the display panel of the present disclosure, each of the fifth protrusions corresponds to each of the second protrusions, and an orthographic projection of the fifth protrusions on the light-emitting substrate coincides with the orthographic projection of the second protrusions on the light-emitting substrate.

In the display panel of the present disclosure, the display panel further comprises a light-emitting device;

wherein the substrate comprises a display area and non-display area;

wherein the light-emitting device is disposed on the display area, and the encapsulation film is disposed on the light-emitting device and covers the substrate; and

wherein the first protrusions are disposed on the non-display area.

Second, the present disclosure provides a display panel, comprising:

a substrate; and

an encapsulation film, the encapsulation film disposed on the substrate, and the encapsulation film comprising laminated a first inorganic layer, a first organic layer, and a second inorganic layer;

wherein a plurality of first protrusions are disposed on a surface of the first inorganic layer facing the first organic layer, and the first organic layer is disposed on the plurality of first protrusions and covers the first inorganic layer.

In the display panel of the present disclosure, each of the plurality of first protrusions comprises a first end portion and a second end portion opposite to each other, and a side portion disposed between the first end portion and the second end portion; and

wherein the first organic layer is disposed along the first end portion and the side portion, and the second end portion connects the first inorganic layer.

In the display panel of the present disclosure, a plurality of second protrusions are disposed on a surface of the first organic layer facing the first inorganic layer; and

wherein the first protrusions are staggered with the second protrusions, and each of all of the second protrusions is disposed between neighboring two of the first protrusions.

In the display panel of the present disclosure, a plurality of third protrusions are disposed on the surface of the first organic layer facing the second inorganic layer, and a plurality of fourth protrusions are disposed on a surface of the second inorganic layer facing the first organic layer; and

wherein the third protrusions are staggered with the fourth protrusions, and each of all of the third protrusions is disposed between neighboring two of the fourth protrusions.

In the display panel of the present disclosure, each of the first protrusions corresponds to each of the fourth protrusions, and each of the second protrusions corresponds to each of the third protrusions.

In the display panel of the present disclosure, an orthographic projection of the first protrusions on the light-emitting substrate coincides with an orthographic projection of the fourth protrusions on the light-emitting substrate; and

wherein an orthographic projection of the second protrusions on the light-emitting substrate coincides with an orthographic projection of the third protrusions on the light-emitting substrate.

In the display panel of the present disclosure, the encapsulation film further comprises a second organic layer and a third inorganic layer; and

wherein a plurality of fifth protrusions are disposed on the surface of the first inorganic layer facing the second organic layer, the second organic layer is disposed on the plurality of fifth protrusions and covers the first inorganic layer, and the third inorganic layer is disposed on the second organic layer.

In the display panel of the present disclosure, each of the fifth protrusions corresponds to each of the second protrusions, and an orthographic projection of the fifth protrusions on the light-emitting substrate coincides with the orthographic projection of the second protrusions on the light-emitting substrate.

In the display panel of the present disclosure, the display panel further comprises a light-emitting device;

wherein the substrate comprises a display area and non-display area;

wherein the light-emitting device is disposed on the display area, and the encapsulation film is disposed on the light-emitting device and covers the substrate; and

wherein the first protrusions are disposed on the non-display area.

Third, the present disclosure provides a display device and comprises a display panel, and the display panel comprising:

a substrate; and

an encapsulation film, the encapsulation film disposed on the substrate, and the encapsulation film comprising laminated a first inorganic layer, a first organic layer, and a second inorganic layer;

wherein a plurality of first protrusions are disposed on a surface of the first inorganic layer facing the first organic layer, and the first organic layer is disposed on the plurality of first protrusions and covers the first inorganic layer.

In the display device of the present disclosure, each of the plurality of first protrusions comprises a first end portion and a second end portion opposite to each other, and a side portion disposed between the first end portion and the second end portion; and

wherein the first organic layer is disposed along the first end portion and the side portion, and the second end portion connects the first inorganic layer.

In the display device of the present disclosure, a plurality of second protrusions are disposed on a surface of the first organic layer facing the first inorganic layer; and

wherein the first protrusions are staggered with the second protrusions, and each of all of the second protrusions is disposed between neighboring two of the first protrusions.

In the display device of the present disclosure, a plurality of third protrusions are disposed on the surface of the first organic layer facing the second inorganic layer, and a plurality of fourth protrusions are disposed on a surface of the second inorganic layer facing the first organic layer; and

wherein the third protrusions are staggered with the fourth protrusions, and each of all of the third protrusions is disposed between neighboring two of the fourth protrusions.

The beneficial effects of the present disclosure are improving the reliability of the OLED panel encapsulation and further increasing the life of OLED devices.

### DESCRIPTION OF DRAWINGS

In order to describe technical solutions in the present disclosure clearly, drawings to be used in the description of embodiments will be described briefly below. Apparently, drawings described below are only for some embodiments of the present disclosure, and other drawings may be obtained by those skilled in the art based on these drawings without creative efforts.

FIG. 1 is a structural diagram of the first embodiment of the display panel provided by the present disclosure;

FIG. 2 is a structural diagram of the second embodiment of the display panel provided by the present disclosure;

FIG. 3 is a structural diagram of the first embodiment of the mask provided by the present disclosure;

FIG. 4 is a structural diagram of the third embodiment of the display panel provided by the present disclosure;

FIG. 5 is a structural diagram of the second embodiment of the mask provided by the present disclosure; and

FIG. 6 is a structural diagram of the fourth embodiment of the display panel provided by the present disclosure.

### DETAILED DESCRIPTION

Embodiments of the present disclosure are described detailly below. Examples of the embodiments are shown in the drawings, and units of the same or similar functions are using the same or similar numeral to represent. Embodiments reference to the appended drawings are used to describe and understand the present disclosure, not to limit the present disclosure.

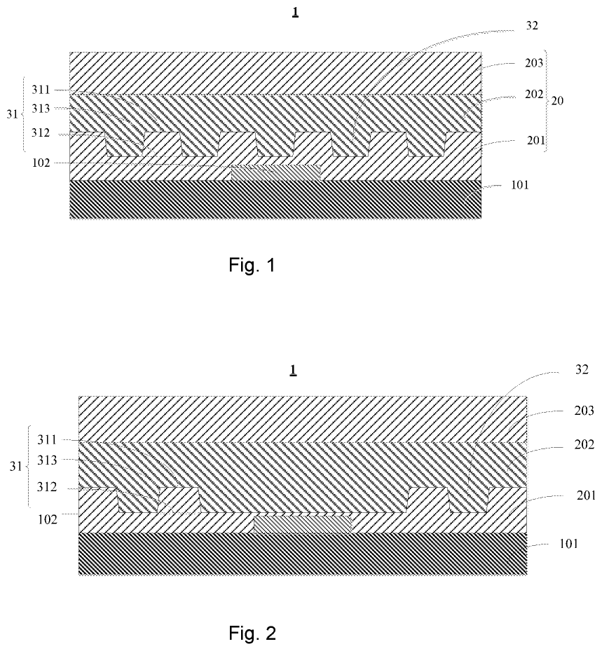

Please refer to FIG. 1, which is a structural diagram of the first embodiment of the display panel provided by the present disclosure.

The present disclosure provides a display panel 1, and includes a substrate 101 and an encapsulation film 20. The encapsulation film 20 is disposed on the substrate 101. The encapsulation film 20 includes laminated a first inorganic layer 201, a first organic layer 202, and a second inorganic layer 203. A plurality of first protrusions 31 are disposed on a surface of the first inorganic layer 201 facing the first organic layer 202. The first organic layer 202 is disposed on the plurality of first protrusions 31 and covers the first inorganic layer 201.

The substrate 101 can be a flexible substrate or a rigid substrate. The substrate 101 can include various circuit structures and/or substrate structures depends on actual demands. The substrate 101 has display area 110 and non-display area 120. For example, the substrate 101 provides a light-emitting device 102. The light-emitting device 102 is disposed on the substrate 101. The encapsulation film 20 is disposed on the light-emitting device 102 and covers the substrate 101. The first protrusions 31 are disposed on the non-display area 120 as shown in FIG. 2.

The light-emitting device can include an anode, a hole layer, a light emitting layer, an electron layer, and a cathode. In operation, under a certain voltage drive, electrons and holes are injected from the anode and the cathode to the electron transport layer and the hole transport layer, and migrate to the light-emitting layer respectively. In the light-emitting layer, they encounter each other, composite together, and release energy. The energy is transmitted to the molecules of the light-emitting substance, and the light-emitting molecules are excited to leap from the ground state to the excited state, the radiation transition produces a light-emitting phenomenon.

Therefore, disposing the plurality of first protrusions 31 on the substrate 101 can avoid the problem of the detachment of the encapsulation film 20. It improves the reliability of the display panel encapsulation and further increases the life of light-emitting devices 102. In addition, disposing the plurality of first protrusions 31 on the non-display area 120 does not affect the light-emitting effect of the substrate 101 as shown in FIG. 2.

Please keep referring to FIG. 1. Each of the plurality of first protrusions 31 includes a first end portion 311 and a second end portion 312 opposite to each other, and a side portion 313 disposed between the first end portion 311 and the second end portion 312. The first organic layer 202 is disposed along the first end portion 311 and the side portion 313, and the second end portion 313 connects the first inorganic layer 201.

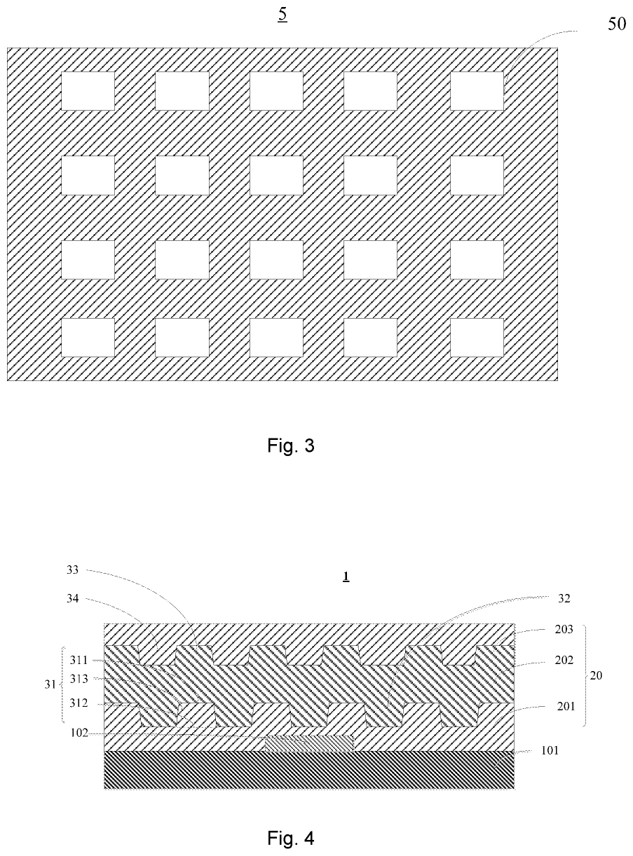

First, the first inorganic layer 201 can be formed on the substrate 101 by using a mask 2, and a structural diagram of the mask 2 is shown in FIG. 3. The mask 5 defines a plurality of holes 50. The number of holes is equal to the number of the first protrusions 31, and the shape of the holes 50 coincides with the shape of the horizontal sectional of the first protrusions 31. The process of forming the first inorganic layer 201 can be the chemical vapor deposition process or another process. Subsequently, the first organic layer 202 can be formed by the inkjet printing process. The first organic layer 202 is disposed along the first end portion 311 and the side portion 313 of the first protrusions 31. Finally, the second inorganic layer 203 is disposed on the first organic layer 202.

In this embodiment, a plurality of second protrusions 32 are disposed on a surface of the first organic layer 202 facing the first inorganic layer 201. The first protrusions 31 are staggered with the second protrusions 32, and each of all of the second protrusions 32 is disposed between neighboring two of the first protrusions 31 as shown in FIG. 1. It needs two steps to form the first organic layer 202. First, an organic material can be filled between neighboring two of the first protrusions 31 by the inkjet printing process. In the photolithography process, the second protrusions 32 are obtained after the organic material is cured. Second, an organic material covers the first inorganic layer 201, the first protrusions 31, and the second protrusions 32 to form the first organic layer 202.

A plurality of second protrusions 32 are disposed on a surface of the first organic layer 202 facing the first inorganic layer 201. It increases the contact area between the first inorganic layer 201 and the first organic layer 202 to avoid the problem of the detachment occurs between the first inorganic layer 201 and the first organic layer 202. It improves the reliability of the display panel encapsulation and further increases the life of light-emitting devices 102.

Please refer to FIG. 4, which is a structural diagram of the third embodiment of the display panel provided by the present disclosure. The present disclosure provides a display panel 1. The differences between the display panel 1 in FIG. 4 and the display panel 1 in FIG. 1 are: a plurality of third protrusions 33 are disposed on the surface of the first organic layer 202 facing the second inorganic layer 203, and a plurality of fourth protrusions 34 are disposed on a surface of the second inorganic layer facing the first organic layer.

The third protrusions 33 are staggered with the fourth protrusions 34, and each of all of the third protrusions 33 is disposed between neighboring two of the fourth protrusions 34.

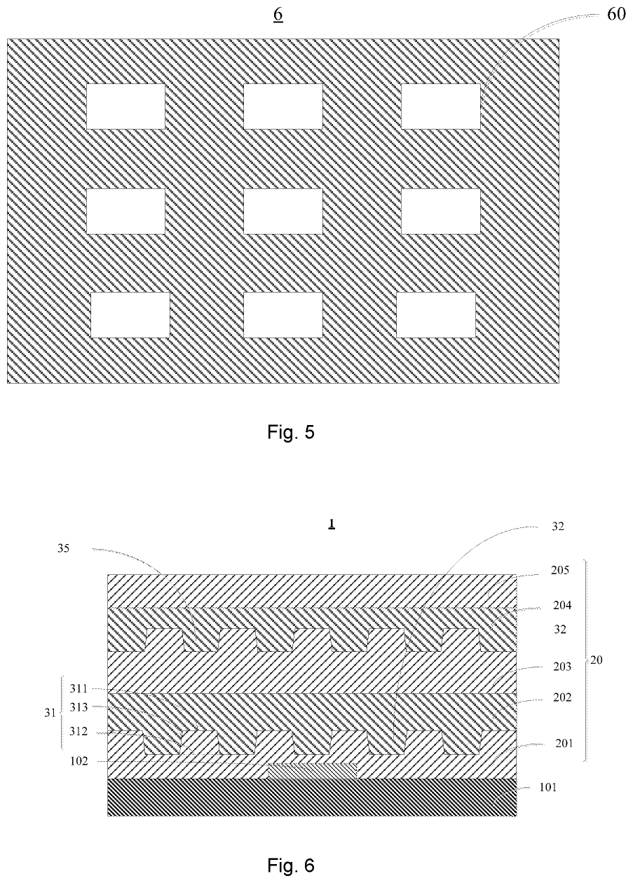

For the method of forming the third protrusions 33 and the fourth protrusions 34, refer to the previous embodiments, and details are not described herein again. After the first organic layer 202 is formed, the plurality of third protrusions 33 are disposed on the surface of the first organic layer 202 facing the second inorganic layer 203 by the photolithography process and using the mask 5 in FIG. 3. Then forming the fourth protrusions 34 between neighboring two of the third protrusions 33 using the mask 6 in FIG. 5. The mask 6 includes a plurality of holes 60. The shape of the holes 60 coincides with the shape of the horizontal sectional of the fourth protrusions 34. Last, forming the second inorganic layer 203 covers a first organic layer 202, the third protrusions 33, and the fourth protrusions 34.

In this embodiment, each of the first protrusions 31 corresponds to each of the fourth protrusions 34, and each of the second protrusions 32 corresponds to each of the third protrusions 33. The benefits of this arrangement are: not only ensure the uniformity of the film thickness of each layer but also solve the problem that the bonding force between two neighboring films is large and the bonding force of the other area is small. And the reliability of the encapsulation can be further improved consequently.

In addition, in this embodiment, an orthographic projection of the first protrusions 31 on the substrate 101 coincides with an orthographic projection of the fourth protrusions 34 on the substrate. An orthographic projection of the second protrusions 32 on the substrate 101 coincides with an orthographic projection of the third protrusions 33 on the substrate 101. The length of one side of the first protrusions 31 close to the first organic layer 202 is L1. The length of one side of the second protrusions 32 close to the first inorganic layer 201 is L2. The length of one side of the third protrusions 33 close to the second inorganic layer 203 is L3. The length of one side of the fourth protrusions 34 close to the first organic layer 202 is L4. The relationship is satisfied at this time: L1=L4, L2=L3.

This ensures that each of the fourth protrusions 34 corresponding to each of the first protrusions 31 coincides with the size of the first protrusions 31. Each of the third protrusions 33 corresponding to each of the second protrusions 32 coincides with the size of the second protrusions 32. Further ensuring the uniformity of the film thickness of each layer and solve the problem that the bonding force between two neighboring films is large and the bonding force of the other area is small. And the reliability of the encapsulation can be further improved consequently.

A plurality of second protrusions 32 are disposed on a surface of the first organic layer 202 facing the first inorganic layer 201. A plurality of third protrusions 33 are disposed on the surface of the first organic layer 202 facing the second inorganic layer 203. A plurality of fourth protrusions 34 are disposed on a surface of the second inorganic layer 203 facing the first organic layer 201. It increases the contact area between the first inorganic layer 201 and the first organic layer 202, and increases the contact area between the first organic layer 202 and the second inorganic layer 203. It avoids the problem of the detachment occurs between the first inorganic layer 201 and the first organic layer 202, and avoids the problem of the detachment occurs between the first organic layer 202 and the second inorganic layer 203. It improves the reliability of the display panel encapsulation and further increases the life of OLED devices.

Please refer to FIG. 6, which is a structural diagram of the fourth embodiment of the display panel provided by the present disclosure. The present disclosure further provides a display panel 1. The difference between the display panel 1 in FIG. 6 and the display panel 1 in FIG. 1 is: the encapsulation film 20 further includes the second organic layer 204 and the third inorganic layer 205.

A plurality of fifth protrusions 35 are disposed on the surface of the first inorganic layer 203 facing the second organic layer 204. The second organic layer 204 is disposed on the plurality of fifth protrusions 35 and covers the first inorganic layer 203. The third inorganic layer 205 is disposed on the second organic layer 204.

For the method of forming the fifth protrusions 35, refer to the previous embodiments, and details are not described herein again. After the second organic layer 204 is formed, a third inorganic layer 205 is disposed on the surface of the second organic layer 204. There are no protrusions disposed on the third inorganic layer 205 to ensure the uniformity of the film thickness.

In addition, in this embodiment, each of the fifth protrusions 35 corresponds to each of the second protrusions 32, and an orthographic projection of the fifth protrusions 35 on the substrate 101 coincides with the orthographic projection of the second protrusions 32 on the substrate 101.

The first protrusions 31, the second protrusions 32, the third protrusions 33, the fourth protrusions 34, and the fifth protrusions 35 are disposed in the encapsulation film 20. It increases the contact area between the first inorganic layer 201 and the first organic layer 202, increases the contact area between the first organic layer 202 and the second inorganic layer 203, and increases the contact area between the second inorganic layer 203 and the second organic layer 204. It avoids the problem of the detachment occurs between the first inorganic layer 201 and the first organic layer 202, avoids the problem of the detachment occurs between the first organic layer 202 and the second inorganic layer 203, and avoids the problem of the detachment occurs between the second inorganic layer 203 and the second organic layer 204. It improves the reliability of the display panel encapsulation and further increases the life of light-emitting devices 102.

Accordingly, the present disclosure further provides a display device. The display device includes a display panel 1, the display panel 1 refers to the previous embodiments, and details are not described herein again.

The display device provided by embodiments of the present disclosure is described in detail above, the specific examples of this document are used to explain principles and embodiments of the present disclosure, and the description of embodiments above is only for helping to understand the present disclosure. Meanwhile, those skilled in the art will be able to change the specific embodiments and the scope of the disclosure according to the idea of the present disclosure. In the above, the content of the specification should not be construed as limiting the present disclosure. Above all, the content of the specification should not be the limitation of the present disclosure.

1. A display panel, comprising:
a substrate; and
an encapsulation film, the encapsulation film disposed on the substrate, and the encapsulation film comprising laminated a first inorganic layer, a first organic layer, and a second inorganic layer;
wherein a plurality of first protrusions are disposed on a surface of the first inorganic layer facing the first organic layer, and the first organic layer is disposed on the plurality of first protrusions and covers the first inorganic layer;
wherein each of the plurality of first protrusions comprises a first end portion and a second end portion opposite to each other, and a side portion disposed between the first end portion and the second end portion;
wherein the first organic layer is disposed along the first end portion and the side portion, and the second end portion connects the first inorganic layer;
wherein a plurality of second protrusions are disposed on a surface of the first organic layer facing the first inorganic layer; and
wherein the first protrusions are staggered with the second protrusions, and each of all of the second protrusions is disposed between neighboring two of the first protrusions.

2. The display panel as claimed in claim 1, wherein a plurality of third protrusions are disposed on the surface of the first organic layer facing the second inorganic layer, and a plurality of fourth protrusions are disposed on a surface of the second inorganic layer facing the first organic layer; and
wherein the third protrusions are staggered with the fourth protrusions, and each of all of the third protrusions is disposed between neighboring two of the fourth protrusions.

3. The display panel as claimed in claim 2, wherein each of the first protrusions corresponds to each of the fourth protrusions, and each of the second protrusions corresponds to each of the third protrusions.

4. The display panel as claimed in claim 3, wherein an orthographic projection of the first protrusions on the substrate coincides with an orthographic projection of the fourth protrusions on the substrate; and
wherein an orthographic projection of the second protrusions on the substrate coincides with an orthographic projection of the third protrusions on the substrate.

5. The display panel as claimed in claim 1, wherein the encapsulation film further comprises a second organic layer and a third inorganic layer; and
wherein a plurality of fifth protrusions are disposed on the surface of the first inorganic layer facing the second organic layer, the second organic layer is disposed on the plurality of fifth protrusions and covers the first inorganic layer, and the third inorganic layer is disposed on the second organic layer.

6. The display panel as claimed in claim 5, wherein each of the fifth protrusions corresponds to each of the second protrusions, and an orthographic projection of the fifth protrusions on the substrate coincides with the orthographic projection of the second protrusions on the substrate.

7. The display panel as claimed in claim 1, wherein the display panel further comprises a light-emitting device;
wherein the substrate comprises a display area and non-display area;
wherein the light-emitting device is disposed on the display area, and the encapsulation film is disposed on the light-emitting device and covers the substrate; and
wherein the first protrusions are disposed on the non-display area.

8. A display panel, comprising:
a substrate; and
an encapsulation film, the encapsulation film disposed on the substrate, and the encapsulation film comprising laminated a first inorganic layer, a first organic layer, and a second inorganic layer;
wherein a plurality of first protrusions are disposed on a surface of the first inorganic layer facing the first organic layer, and the first organic layer is disposed on the plurality of first protrusions and covers the first inorganic layer.

9. The display panel as claimed in claim 8, wherein each of the plurality of first protrusions comprises a first end portion and a second end portion opposite to each other, and a side portion disposed between the first end portion and the second end portion; and
wherein the first organic layer is disposed along the first end portion and the side portion, and the second end portion connects the first inorganic layer.

10. The display panel as claimed in claim 9, wherein a plurality of second protrusions are disposed on a surface of the first organic layer facing the first inorganic layer; and
wherein the first protrusions are staggered with the second protrusions, and each of all of the second protrusions is disposed between neighboring two of the first protrusions.

11. The display panel as claimed in claim 10, wherein a plurality of third protrusions are disposed on the surface of the first organic layer facing the second inorganic layer, and a plurality of fourth protrusions are disposed on a surface of the second inorganic layer facing the first organic layer; and
wherein the third protrusions are staggered with the fourth protrusions, and each of all of the third protrusions is disposed between neighboring two of the fourth protrusions.

12. The display panel as claimed in claim 11, wherein each of the first protrusions corresponds to each of the fourth protrusions, and each of the second protrusions corresponds to each of the third protrusions.

13. The display panel as claimed in claim 12, wherein an orthographic projection of the first protrusions on the substrate coincides with an orthographic projection of the fourth protrusions on the substrate; and
wherein an orthographic projection of the second protrusions on the substrate coincides with an orthographic projection of the third protrusions on the substrate.

14. The display panel as claimed in claim 10, wherein the encapsulation film further comprises a second organic layer and a third inorganic layer; and
wherein a plurality of fifth protrusions are disposed on the surface of the first inorganic layer facing the second organic layer, the second organic layer is disposed on the plurality of fifth protrusions and covers the first inorganic layer, and the third inorganic layer is disposed on the second organic layer.

15. The display panel as claimed in claim 14, wherein each of the fifth protrusions corresponds to each of the second protrusions, and an orthographic projection of the fifth protrusions on the substrate coincides with the orthographic projection of the second protrusions on the substrate.

16. The display panel as claimed in claim 8, wherein the display panel further comprises a light-emitting device;
wherein the substrate comprises a display area and non-display area;
wherein the light-emitting device is disposed on the display area, and the encapsulation film is disposed on the light-emitting device and covers the substrate; and
wherein the first protrusions are disposed on the non-display area.

17. A display device comprises a display panel;
the display panel comprising:
a substrate; and
an encapsulation film, the encapsulation film disposed on the substrate, and the encapsulation film comprising laminated a first inorganic layer, a first organic layer, and a second inorganic layer;
wherein a plurality of first protrusions are disposed on a surface of the first inorganic layer facing the first organic layer, and the first organic layer is disposed on the plurality of first protrusions and covers the first inorganic layer.

18. The display device as claimed in claim 17, wherein each of the plurality of first protrusions comprises a first end portion and a second end portion opposite to each other, and a side portion disposed between the first end portion and the second end portion; and
wherein the first organic layer is disposed along the first end portion and the side portion, and the second end portion connects the first inorganic layer.

19. The display device as claimed in claim 18, wherein a plurality of second protrusions are disposed on a surface of the first organic layer facing the first inorganic layer; and
wherein the first protrusions are staggered with the second protrusions, and each of all of the second protrusions is disposed between neighboring two of the first protrusions.

20. The display device as claimed in claim 19, wherein a plurality of third protrusions are disposed on the surface of the first organic layer facing the second inorganic layer, and a plurality of fourth protrusions are disposed on a surface of the second inorganic layer facing the first organic layer; and
wherein the third protrusions are staggered with the fourth protrusions, and each of all of the third protrusions is disposed between neighboring two of the fourth protrusions.
